(19) United States
(12) Patent Application Publication
(10) Pub. No.: US 2026/0212917 A1
(43) Pub. Date: Jul. 23, 2026

(54) DRIVER AND TERMINATION (ZQ) CALIBRATION CIRCUITRY

(71) Applicant: Micron Technology, Inc., Boise, ID (US)

(72) Inventors: Chulkyu Lee, Meridian, ID (US); Timothy M. Hollis, Meridian, ID (US)

(21) Appl. No.: 19/412,084

(22) Filed: Dec. 8, 2025

Related U.S. Application Data
(60) Provisional application No. 63/747,190, filed on Jan. 20, 2025.

(51) Int. Cl. G11C 11/4093

(52) U.S. Cl. CPC G11C 11/4093

(57) ABSTRACT

Systems and methods include a memory device that includes ZQ calibration circuitry that includes a ZQ resistor. The system also includes multiple driver unit circuitries configured to be calibrated using the ZQ resistor. At least one of the plurality of driver unit circuitries includes multiple sub-drivers. The multiple sub-drivers include a first set of sub-drivers each having a first impedance and a second set of sub-drivers each having a second impedance that is different than the first impedance.

### CROSS-REFERENCE TO RELATED APPLICATIONS

This application claims priority to U.S. Provisional Application No. 63/747,190, filed Jan. 20, 2025, which is incorporated by reference herein in its entirety.

### BACKGROUND

### Field of the Invention

Embodiments of the present disclosure relate generally to the field of semiconductor memory devices. More specifically, embodiments of the present disclosure relate to a driver and termination calibration circuitry in a dynamic random access memory (DRAM) device.

### Description of the Related Art

The operational rate of memory devices, including the data rate of a memory device, has been increasing over time. As a side effect of the increase in speed of a memory device, data errors may become more problematic. For example, memory devices may be susceptible to voltage and/or temperature variations that may negatively impact signal integrity and/or data reliability especially in high-speed memory systems. To compensate for such variations in voltage and/or temperature, memory devices may utilize driver and termination (ZQ) calibration to fine tune a memory's internal impedance to maintain optimal signal quality across different operating conditions. Such calibration may use a dedicated ZQ pin connected to a precision external resistor that acts as a reference point to calibrate the internal drive strength and termination resistance of the memory device. By calibrating such internal drive strength and termination, ZQ calibration circuitry minimizes signal reflections and ensures reliable data transmission even at high frequencies. This calibration increases memory bandwidth and performance and reduces errors. The ZQ calibration may also be used to drive an output driver of the memory device. However, these output drivers may add parasitic capacitance (CIO) to the system that may negatively impact performance especially at high speeds.

### BRIEF DESCRIPTION OF THE DRAWINGS

Various aspects of this disclosure may better be understood upon reading the following detailed description and upon reference to the drawings in which:

FIG. 1 is a simplified block diagram illustrating certain features of a memory device that includes ZQ calibration circuitry and output driver(s), according to an embodiment of the present disclosure;

FIG. 2 illustrates a block diagram of an embodiment of the ZQ calibration circuitry, according to an embodiment of the present disclosure;

FIG. 3 illustrates an output driver of FIG. 1 including multiple pull-up sub-drivers and multiple pull-down sub-drivers, according to an embodiment of the present disclosure;

FIG. 4 illustrates a schematic diagram of an embodiment of one of the multiple pull-up sub-drivers and one of the multiple pull-down sub-drivers of FIG. 3, according to an embodiment of the present disclosure;

FIG. 5 is a block diagram of an output driver of FIG. 1 including multiple heterogeneous pull-up sub-drivers and multiple heterogeneous pull-down sub-drivers, according to an embodiment of the present disclosure; and

FIG. 6 is a flow diagram illustrating using the ZQ calibration circuitry in the memory device of FIG. 1, according to an embodiment of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

As is discussed below, output drivers of a memory device may be a relatively large contributor to overall CIO of the memory device. The output drivers may be sliced/divided into slices/sub-drivers. As is discussed below, the slices/sub-drivers of the drivers that control impedance of the ZQ circuitry may increase the CIO of the memory device. Accordingly, to reduce the impact of the output drivers to the CIO, fewer slices/output drivers may be deployed in the output drivers to reduce the CIO contributed by the output drivers. However, the output drivers may still need to meet standards requirements where the drivers are configurable for different impedances, such as 34 Ω, 40 Ω, 48 Ω, 60 Ω, 80 Ω, 120Ω, and 240Ω. For instance, the output drivers may be driven to a specific value (e.g., 34 Ω, 40Ω, or 48Ω or another value such as 50Ω) while using the other values during write operations where the output driver provides on-die termination (ODT). To still meet these different configurable impedances with fewer drivers, the drivers may have heterogeneous impedances to provide additional flexibility to enable the memory device to provide each of the required impedances with fewer drivers.

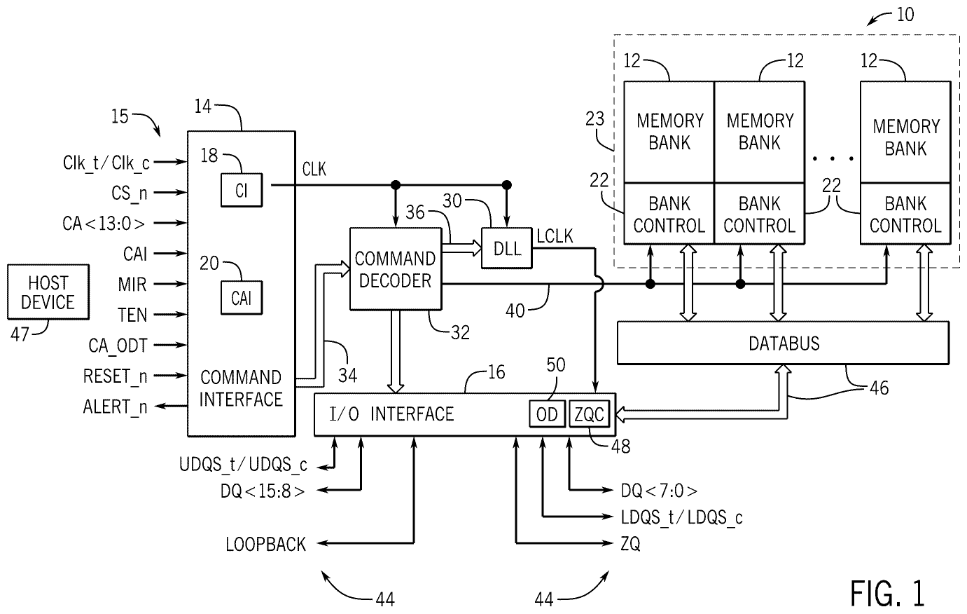

Turning now to the figures, FIG. 1 is a simplified block diagram illustrating certain features of a memory device 10. Specifically, the block diagram of FIG. 1 is a functional block diagram illustrating certain functionality of the memory device 10. In accordance with one embodiment, the memory device 10 may be a double data rate type four (DDR4 SDRAM), a double data rate type five synchronous dynamic random-access memory (DDR5 SDRAM) device, a low-power double data rate type four (LPDDR4 SDRAM), a low-power double data rate type five (LPDDR5 SDRAM), and/or another new type, such as double data rate type six (DDR6 SDRAM). Various features of DDR SDRAM devices allow for reduced power consumption, more bandwidth and more storage capacity compared to prior generations of DDR SDRAM.

The memory device 10 may include a number of memory banks 12. The memory banks 12 may be DDR6 SDRAM memory banks, for instance. The memory banks 12 may be provided on one or more chips (e.g., SDRAM chips) that are arranged on dual inline memory modules (DIMMS). Each DIMM may include a number of SDRAM memory chips (e.g., x8 or x16 memory chips), as will be appreciated. Each SDRAM memory chip may include one or more memory banks 12. The memory device 10 represents a portion of a single memory chip (e.g., SDRAM chip) having a number of memory banks 12. For DDR, the memory banks 12 may be further arranged to form bank groups. For instance, for an 8 gigabit (Gb) DDR5 SDRAM, the memory chip may include 16 memory banks 12, arranged into 8 bank groups, each bank group including 2 memory banks. For a 16 GB DDR5 SDRAM, the memory chip may include 32 memory banks 12, arranged into 8 bank groups, each bank group including 4 memory banks, for instance. Various other configurations, organization, and sizes of the memory banks 12 on the memory device 10 may be utilized depending on the application and design of the overall system.

The memory device 10 may include a command interface 14 and an input/output (I/O) interface 16 configured to exchange (e.g., receive and transmit) signals with external devices. The command interface 14 is configured to provide a number of signals (e.g., signals 15) from an external device (not shown), such as a processor or controller. The processor or controller may provide various signals 15 to the memory device 10 to facilitate the transmission and receipt of data to be written to or read from the memory device 10.

As will be appreciated, the command interface 14 may include a number of circuits, such as a clock input circuit 18 and a command address input circuit 20, for instance, to ensure proper handling of the signals 15. The command interface 14 may receive one or more clock signals from an external device. Generally, double data rate (DDR) memory utilizes a differential pair of system clock signals, referred to herein as the true clock signal (Clk_t) and the complementary clock signal (Clk_c). The positive clock edge for DDR refers to the point where the rising true clock signal Clk_t crosses the falling complementary clock signal Clk_c, while the negative clock edge indicates that transition of the falling true clock signal Clk_t and the rising of the complementary clock signal Clk_c. Commands (e.g., read command, write command, etc.) are typically entered on the positive edges of the clock signal and data is transmitted or received on both the positive and negative clock edges.

The clock input circuit 18 receives the true clock signal (Clk_t) and the complementary clock signal (Clk_c) and generates an internal clock signal CLK. The internal clock signal CLK is supplied to an internal clock generator 30, such as a delay locked loop (DLL) circuit. The internal clock generator 30 generates a phase controlled internal clock signal LCLK based on the received internal clock signal CLK. The phase controlled internal clock signal LCLK is supplied to the I/O interface 16, for instance, and is used as a timing signal for determining an output timing of read data.

The internal clock signal CLK may also be provided to various other components within the memory device 10 and may be used to generate various additional internal clock signals. For instance, the internal clock signal CLK may be provided to a command decoder 32. The command decoder 32 may receive command signals from the command bus 34 and may decode the command signals to provide various internal commands. For instance, the command decoder 32 may provide command signals to the internal clock generator 30 over the bus 36 to coordinate generation of the phase controlled internal clock signal LCLK. The phase controlled internal clock signal LCLK may be used to clock data through the I/O interface 16, for instance.

Further, the command decoder 32 may decode commands, such as read commands, write commands, mode-register set commands, activate commands, etc., and provide access to a particular memory bank 12 corresponding to the command, via the bus path 40. As will be appreciated, the memory device 10 may include various other decoders, such as row decoders and column decoders, to facilitate access to the memory banks 12. In one embodiment, each memory bank 12 includes a bank control block 22 which provides the necessary decoding (e.g., row decoder and column decoder), as well as other features, such as timing control and data control, to facilitate the execution of commands to and from the memory banks 12. Collectively, the memory banks 12 and the bank control blocks 22 may be referred to as a memory array 23.

The memory device 10 executes operations, such as read commands and write commands, based on the command/address signals received from an external device, such as a processor. In one embodiment, the command/address bus may be a 14-bit bus to accommodate the command/address signals (CA<13:0>). The command/address signals are clocked to the command interface 14 using the clock signals (Clk_t and Clk_c). The command interface may include a command address input circuit 20 which is configured to receive and transmit the commands to provide access to the memory banks 12, through the command decoder 32, for instance. In addition, the command interface 14 may receive a chip select signal (CS_n). The CS_n signal enables the memory device 10 to process commands on the incoming CA<13:0> bus. Access to specific banks 12 within the memory device 10 is encoded on the CA<13:0> bus with the commands.

In addition, the command interface 14 may be configured to receive a number of other command signals. For instance, a command/address on die termination (CA_ODT) signal may be provided to facilitate proper impedance matching within the memory device 10. A reset command (RESET_n) may be used to reset the command interface 14, status registers, state machines and the like, during power-up for instance. The command interface 14 may also receive a command/address invert (CAI) signal which may be provided to invert the state of command/address signals CA<13:0> on the command/address bus, for instance, depending on the command/address routing for the particular memory device 10. A mirror (MIR) signal may also be provided to facilitate a mirror function. The MIR signal may be used to multiplex signals so that they can be swapped for enabling certain routing of signals to the memory device 10, based on the configuration of multiple memory devices in a particular application. Various signals to facilitate testing of the memory device 10, such as the test enable (TEN) signal, may be provided, as well. For instance, the TEN signal may be used to place the memory device 10 into a test mode for connectivity testing.

The command interface 14 may also be used to provide an alert signal (ALERT_n) to the system processor or controller for certain errors that may be detected. For instance, an alert signal (ALERT_n) may be transmitted from the memory device 10 if a cyclic redundancy check (CRC) error is detected. Other alert signals may also be generated. Further, the bus and pin for transmitting the alert signal (ALERT_n) from the memory device 10 may be used as an input pin during certain operations, such as the connectivity test mode executed using the TEN signal, as described above.

Data may be sent to and from the memory device 10, utilizing the command and clocking signals discussed above, by transmitting and receiving data signals 44 through the I/O interface 16. More specifically, the data may be sent to or retrieved from the memory banks 12 over a data bus 46 that includes multiple bi-directional data connections. Data I/O signals, generally referred to as DQ signals, are generally transmitted and received in one or more bi-directional data connections. For certain memory devices, such as a DDR5 SDRAM memory device, the I/O signals may be divided into upper and lower bytes. For instance, for an x16 memory device, the I/O signals may be divided into upper and lower I/O signals (e.g., DQ<15:8> and DQ<7:0>) corresponding to upper and lower bytes of the data signals, for instance.

To allow for higher data rates within the memory device 10, certain memory devices, such as DDR memory devices may utilize data strobe signals, generally referred to as DQS signals. The DQS signals are driven by the external processor or controller sending the data (e.g., for a write command) or by the memory device 10 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the data strobe (DQS) signals may be provided as a differential pair of data strobe signals (DQS_t and DQS_c) to provide differential pair signaling during reads and writes. For certain memory devices, such as a DDR5 SDRAM memory device, the differential pairs of DQS signals may be divided into upper and lower data strobe signals (e.g., UDQS_t and UDQS_c; LDQS_t and LDQS_c) corresponding to upper and lower bytes of data sent to and from the memory device 10, for instance. In some embodiments as discussed below, the DQS may be internally generated from a clock received at the memory device 10 from the host device 47. In some such embodiments the DQS pins may be omitted from the memory device 10.

An impedance (ZQ) calibration signal may also be provided to the memory device 10 through the I/O interface 16. The ZQ calibration signal may be provided to a reference pin and used to tune output drivers and ODT values by adjusting pull-up and pull-down resistances of the memory device 10 across changes in process, voltage, and temperature (PVT) values. Because PVT characteristics may impact the ZQ resistor values, the ZQ calibration signal may be provided to the ZQ reference pin to be used to adjust the resistance to calibrate the input and output impedances to known values. As will be appreciated, a precision resistor is generally coupled between the ZQ pin on the memory device 10 and GND/VSS external to the memory device 10. This resistor acts as a reference for adjusting internal ODT and drive strength of the IO pins.

In addition, a loopback signal (LOOPBACK) may be provided to the memory device 10 through the I/O interface 16. The loopback signal may be used during a test or debugging phase to set the memory device 10 into a mode wherein signals are looped back through the memory device 10 through the same pin. For instance, the loopback signal may be used to set the memory device 10 to test the data output of the memory device 10. Loopback may include both a data and a strobe or possibly just a data pin. This is generally intended to be used to monitor the data captured by the memory device 10 at the I/O interface 16.

As will be appreciated, various other components such as power supply circuits (for receiving external VDD and VSS signals), mode registers (to define various modes of programmable operations and configurations), read/write amplifiers (to amplify signals during read/write operations), temperature sensors (for sensing temperatures of the memory device 10), etc., may also be incorporated into the memory system 10. Accordingly, it should be understood that the block diagram of FIG. 1 is only provided to highlight certain functional features of the memory device 10 to aid in the subsequent detailed description.

In some embodiments, the memory device 10 may be coupled to a host device 47. The host device 47 may include a processor, such as a central processing unit (CPU), a graphics processing unit (GPU), another microprocessor, a programmable logic device, and/or any other suitable processor that controls processing of system functions and requests. Further, any host device/processor may include multiple processing units.

The I/O interface 16 may also include ZQ calibration circuitry (ZQC) 48 that performs ZQ calibration during startup and/or periodically during operation of the memory device 10. Specifically, as discussed below, the ZQC 48 calibrates an internal termination and driving level for operation of the memory device 10, which generally includes identifying the internal circuit configuration that best matches the target behavior based on the relationship between the internal circuitry and the external RZQ resistor. Furthermore, the memory device 10 may include output drivers (OD) 50 that are controlled based on calibration values from the ZQ circuitry.

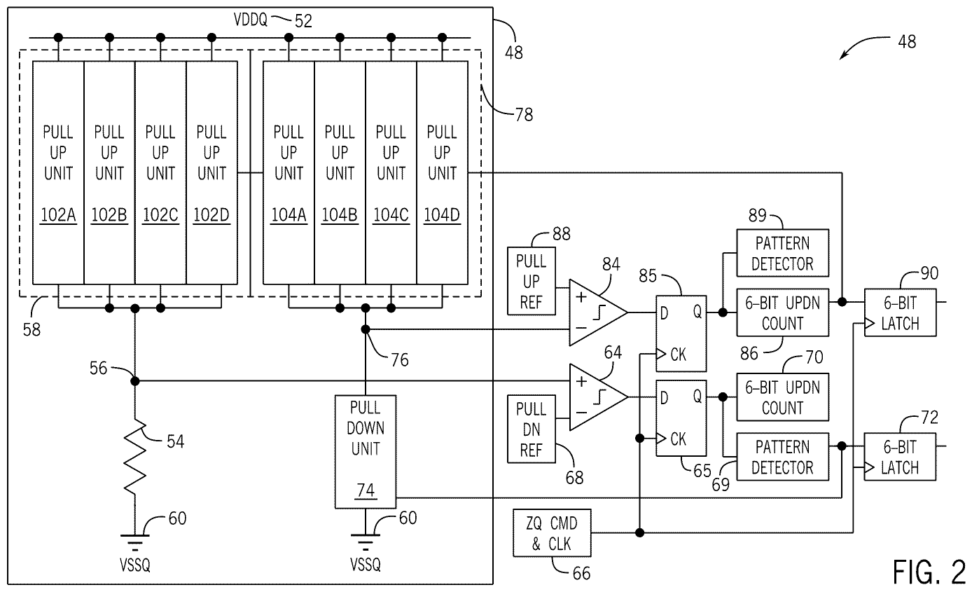

FIG. 2 is a block diagram of an embodiment of the ZQC 48. For example, the ZQC 48 may be similar to ZQCs used in LPDDR4 SDRAM devices, LPDDR5 SDRAM devices, or LPDDR type 6 (LPDDR6 SDRAM devices). As such, the ZQC 48 includes a connection to VDDQ 52. In some embodiments, VDDQ 52 may be supplied to the memory device 10 from outside of the memory die 10 and/or may be an internally generated voltage. For instance, the VDDQ 52 may be supplied by PMIC of the host device 47 and/or controlled by the host device 47 and/or may be generated using a voltage generator (e.g., a bandgap voltage generator) of the memory device 10. For instance, this VDDQ 52 may be connected to the memory device 10 via the ZQ pin and via a precision external resistor (RZQ) 54.

The RZQ 54 may be tuned to a specific impedance (e.g., 240Ω or 120Ω and connected to VSSQ 60. This RZQ 54 acts as a reference to calibrate the termination impedance and drive strength of the memory device 10. By performing ZQ calibration during startup and/or at different intervals, the memory device 10 may compensate for voltage and/or temperature variations.

The RZQ 54 may be coupled to a node 56 that is then terminated to VDDQ 52 through a pull-up unit driver (PUP) 58. The PUP 58 may include multiple legs that are tuned to a specific impedance (e.g., 240Ω using a series resistor coupled to a transistor (e.g., a pull-down NMOS transistor) that acts as legs of a voltage divider. The PUP 58 may match a driver architecture of the memory device 10. For instance, the driver architecture may be a NMOS-over-NMOS low-voltage swing-terminated logic (LVSTL)-based interface or another suitable driver architecture. As will be discussed below later, the PUP 58 may be made up of multiple driver units each including resistors and multiple MOS devices that add up to a target impedance value (e.g., 120Ω or 240Ω).

The ZQC 48 attempts to match the impedance of the PUP 58 to the RZQ 54 at least to some proportion (e.g., one-to-one, four-to-five, etc.). To achieve this match, the ZQC 48 includes a comparator 64, such as an op-amp, that has its non-inverting input coupled to the node 56 and has its inverting input coupled to a pull-down reference voltage (Pull Dn Ref) 68. The Pull Dn Ref 68 may be received from outside of the memory device 10 and/or may be generated within the memory device 10. For instance, the Pull Dn Ref 68 may be generated using a bandgap generation circuitry and/or any other circuitry. This Pull Dn Ref 68 may be proportional to the VDDQ 52, such as four-fifths, one-half, one-third, and the like. For instance, if Pull Dn Ref 68 is half of the voltage of VDDQ 52, the voltage of the node 56 is equal to the Pull Dn Ref 68 when the impedance of the RZQ 54 is equal to the impedance of the PUP 58. One method of achieving this proportionality is to set the proportion based on the number of driver units in the PUP 58. For instance, if 4 parallel driver units of the PUP 58 have the same impedance as the RZQ 54, the voltage at the node 56 is ⅘^{th} or 0.8*the level of VDDQ 52.

The comparator 64 compares the Pull Dn Ref 68 to the voltage of the node 56. When the voltage of the node 56 is smaller than the Pull Dn Ref 68, the comparator 64 outputs a first value (e.g. 0) indicating that the impedance of the PUP 58 is larger than the target (e.g., 240Ω or 120Ω. However, when the volage of the node is greater than the Pull Dn Ref 68, the comparator outputs a second value (e.g., 1) indicating that the impedance of the PUP 58 is smaller than the target. These values may be latched into a flip flop 65 using a ZQ command and clock signal (ZQ CMD & CLK) 66.

An output of the comparator 64 from the flip flop 65 is transmitted to a counter 70. When the output of the comparator 64 indicates the first value, the counter 70 may increment while the second value causes the counter to decrement. This counter contains a code that indicates how the PUP 58 is driven by adjusting the impedance in the PUP 58. In other words, the output of the counter 70 is fed back into the PUP 58, adjusting its impedance for every change of the counter 70. This value being fed back to the PUP 58 is also stored in an output latch 72.

In operation, the counter 70 steps through the calibration until the trip point of the calibration where the voltage of the node 56 is equal to the Pull Dn Ref 68. For instance, the trip point may occur when the impedance of the RZQ 54 is equal to the impedance of the PUP 58. After this tipping point, the counter 70 stops counting and/or reverses count. As a result, the counter is set with a ZQ code adjust signal to set the impedance of the PUP 58 to the target value (e.g., equal to the impedance of the RZQ 54).

In some embodiments, the ZQC 48 includes a pattern detector 69. The pattern detector 69 detects when value flips across the tripping point occur by looking for a pattern of comparator 64 outputs (e.g., 101) indicating that the PUP 58 is calibrated and the next step is to be performed in the calibration. At this time, the ZQ code adjust signal output from the counter 70 is set in the output latch 72, and the ZQC 48 begins calibrating.

While incrementing the ZQ code adjust signal, the ZQC 48 may submit the ZQ code adjust signal to the PUP 58 along with another PUP 78 that is similarly terminated to VDDQ 52. The PUP 78 may be constructed similarly to the PUP 58 such that the two may be driven to the same impedance with the same input. This causes the impedance of the PUP 78 to be equal to or at least proportional to the impedance of the PUP 58. In some embodiments, the impedance of the RZQ 54, the PUP 58, and the PUP 78 are all the same once the calibration of the PUP 58 has been completed. Each of the PUP 58 and the PUP 78 pulls a respective node, the node 56 and the node 76, up toward VDDQ 52.

After setting the impedance in the PUP 78, the ZQC 48 sets the impedance of a pull-down unit/driver (PDN) 74. The PDN 74 may be similar to the PUP 58 and/or 74 except that PDN 74 pulls the node 76 down toward VSSQ 60 rather than pulling the nodes 56 or 76 up toward VDDQ 52. Calibration of the PDN 74 uses a code adjust signal that is like the ZQ code adjust signal used for the PUPs 58 and 78 except that the final result of the code adjust signal is to set the impedance of the PDN 74 proportional to (e.g., the same as) that of the RZQ 54. This proportionality of the impedance of the PDN 74 to the impedance of the RZQ 54 may be independent from the proportion of the impedances of the PUP 58 and the PUP 78 to the RZQ 54. In other words, the impedance of the PDN 74 may be the same as the impedance of the RZQ 54 even if the Pull Dn Ref 68 is not half of VDDQ 52.

To set the impedance of the PDN 74, the ZQC 48 includes a comparator 84 that is coupled to a pull-up reference voltage (Pull Up Ref) 88 and to the node 76. For instance, the non-inverting input of the comparator 84 may be coupled to the node 76 while the inverting input of the comparator 84 may be coupled to the Pull Up Ref 88. In some embodiments, the Pull Up Ref 88 may be the same as the Pull Dn Ref 68. In other embodiments, they are different. Furthermore, since the calibration of the PUP 58 should result in the voltage of the node 56 equal to the Pull Dn Ref 68, the Pull Up Ref 88 may be replaced by a connection to the node 56 in some embodiments.

The comparator 84 may operate similar to the comparator 64 outputting values indicative of the impedance of the PDN 74. Like the comparator 64, the comparator 84 may walk through different values using a counter 86 based on values from the comparator 84 stored in a flip flop 85. A pattern detector 89 may function similarly to the pattern detector 69 to find when calibration has been ended (e.g., a tipping point). The tipping point when the code adjust signal is set is when the voltage of the node 56 is equal to the node 76, and when stored values from the counter 86 stored in an output latch 90 may be used. This point occurs when the impedance of the PDN 74 is equal to the impedance of the RZQ 54 because the impedances of the PUPs 58 and 74 are the same. This is true since each channel is coupled between VDDQ 52 and VSSQ 60 and the impedances of the PDN 74 and RZQ 54 match while the impedances of the PUP 58 and the PUP 78 match. In this state, the ZQ calibration has been completed, and memory operations may be performed using the ZQ calibration values stored in the output latches 72 and 90.

As previously noted, the PUP 58, the PUP 78, and/or the PDN 74 may be sub-divided into multiple different individual units that include individual driver circuitries. For instance, the PUP 58 may be sub-divided into multiple driver units 102A, 102B, 102C, and 102D (collectively referred to as PUP driver units 102). Likewise, the PUP 78 may be sub-divided into multiple driver units 104A, 104B, 104C, and 104D (collectively referred to as PUP driver units 104). Similarly, the PDN 74 may likewise be sub-divided into multiple driver units (not shown for simplicity). Although the illustrated number of PUP driver units 102 and 104 are four driver units each, certain embodiments may include any suitable number of driver units. Furthermore, the number of driver units in the PUP driver units 102, the number of driver units in the PUP driver units 104, and/or the number of driver units in the PDN 74 may be the same as each other or may be different than each other depending on the embodiment deployed without varying from the scope of the teachings herein. In the illustrated embodiment, with each PUP driver unit 102 and 104 set to the impedance of the RZQ 54 and having a total of four units each having the impedance of the RZQ 54, the voltages of the nodes 56 and 76 would be ⅘ths of VDDQ 52.

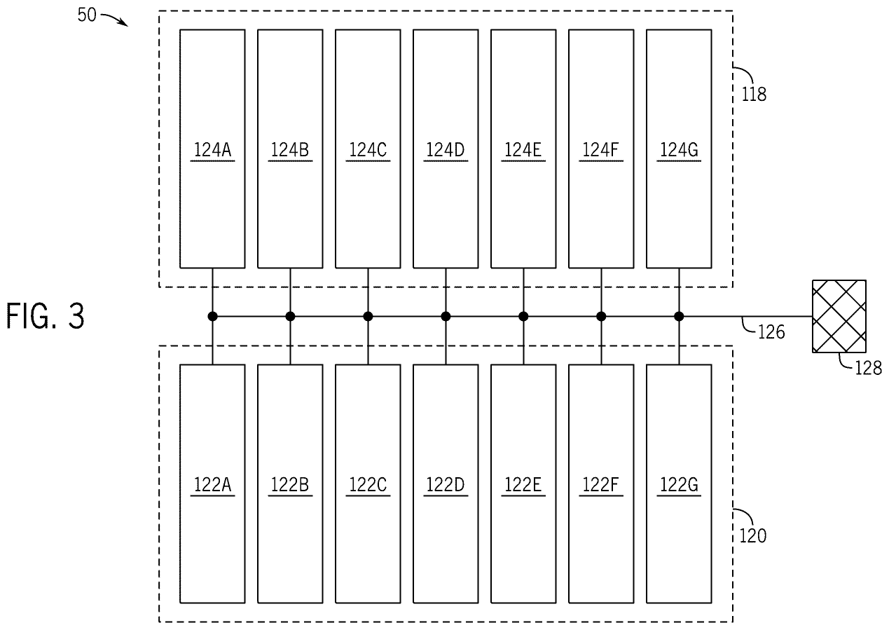

FIG. 3 is a block diagram of an embodiment of the output driver 50. The illustrated view of the output driver may be configured using the calibration values determined from the ZQC 48. Each PDN driver unit 120 may include a number of sub-drivers 122, individually referred to as sub-drivers 122A, 122B, 122C, 122D, 122E, 122F, and 122G. Similarly, each PUP driver unit 118 may include a number of sub-drivers 124, individually referred to as sub-drivers 124A, 124B, 124C, 124D, 124E, 124F, and 124G. The illustrated embodiment includes seven sub-drivers 122 and seven sub-drivers 124 that are connected in parallel to an interconnection 126 (e.g., a wire) that is connected to remaining portions 128 via a pad or other connection. In some embodiments, each of the sub-drivers 122 and 124 may be homogenous in that the impedance of the totality of their internal components (e.g., resistors and transistors) are the same between each sub-driver 122 and 124. In other words, each of the sub-drivers 122 and 124 may have a same total impedance (e.g., 240Ω or 120Ω as each other and as the RZQ 54. Thus, each of the sub-drivers 122 may have a same structure as each other while each of the sub-drivers 124 may have a same structure as each other.

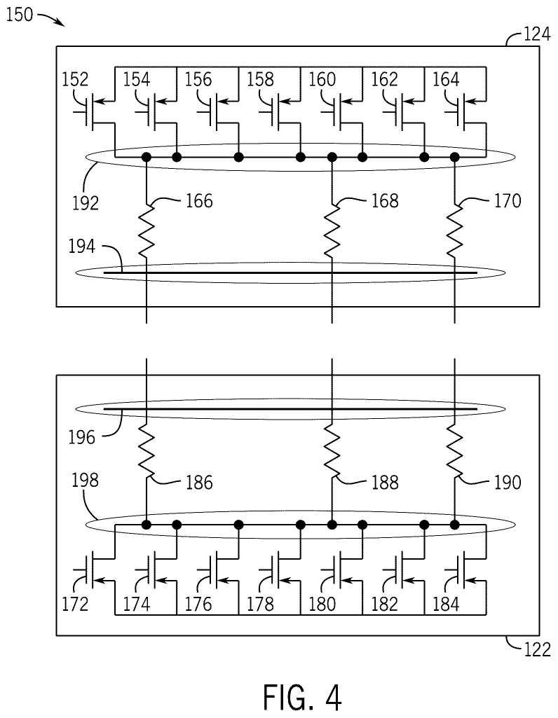

FIG. 4 is a circuit diagram of output driver 50 specifically showing a single sub-driver 122 and a single sub-driver 124. As previously noted, each driver unit includes multiple sub-drivers, but a single sub-driver 122 and a single sub-driver 124 are shown for simplicity of illustration. As illustrated, the sub-driver 124 includes transistors 152, 154, 156, 158, 160, 162, and 164 that have their source and drain terminals coupled in parallel to one or more resistors 166, 168, and 170. Each gate terminal of the transistors 152, 154, 156, 158, 160, 162, and 164 may receive a control signal to control whether the respective transistor is on or off. In some embodiments, the resistors 166, 168, and 170 may be coupled in parallel between the transistors 152, 154, 156, 158, 160, 162, and 164 and the interconnection 126.

The sub-driver 122 includes transistors 172, 174, 176, 178, 180, 182, and 184 that have their source and drain terminals coupled in parallel to one or more resistors 186, 188, and 190. Each gate terminal of the transistors 172, 174, 176, 178, 180, 182, and 184 may receive a control signal to control whether the respective transistor is on or off. In some embodiments, the resistors 186, 188, and 190 may be coupled in parallel between the transistors 172, 174, 176, 178, 180, 182, and 184 and the interconnection 126.

As illustrated, the transistors 152, 154, 156, 158, 160, 162, and 164 use a wire 192 to couple to the resistors 166, 168, and 170 while the resistors 166, 168, and 170 use a wire 194 to connect the resistors 166, 168, and 170 together and to connect to the interconnection 126. Likewise, the transistors 172, 174, 176, 178, 180, 182, and 184 use a wire 198 to couple to the resistors 186, 188, and 190 while the resistors 186, 188, and 190 use a wire 196 to couple the resistors 186, 188, and 190 together and to connect to the interconnection 126. As may be appreciated, the wires 192 and 194 may capacitively couple together and jointly and/or separately increase the CIO of the memory device 10 for each sub-unit 124 included in the memory device 10. Likewise, the wires 196 and 198 may capacitively couple together and jointly and/or separately increase the CIO of the memory device 10 for each sub-unit 122 included in the memory device 10. Furthermore, the amount of capacitance may increase related to the amount of wiring/interconnections present for the respective transistors and resistors of the sub-drivers 122 and 124. The amount of capacitance contributed by the sub-drivers 122 and 124 of the output drivers 50 impacts the overall CIO of the memory device 10. Indeed, the sub-drivers may be a relatively large contributor to CIO of the memory device 10. To increase speed of operation of the memory device 10, it may be desirable to lower the CIO of the memory device 10.

One approach for lowering the CIO for the memory device 10 includes reducing the number of sub-drivers 122 and/or 124 in the memory device 10. However, this may complicate the issue in deriving the proper impedance for the driver units that contain the sub-drivers. For instance, in some embodiments, the number of impedance levels (e.g., 7) may be the same as the number of sub-drivers in a driver to achieve the different impedance levels. One mechanism for reducing the number of sub-drivers may be to have at least one of the sub-drivers to have a different impedance level (e.g., maximum) to maintain the capability to have the various different impedances (e.g., for on-die termination (ODT)).

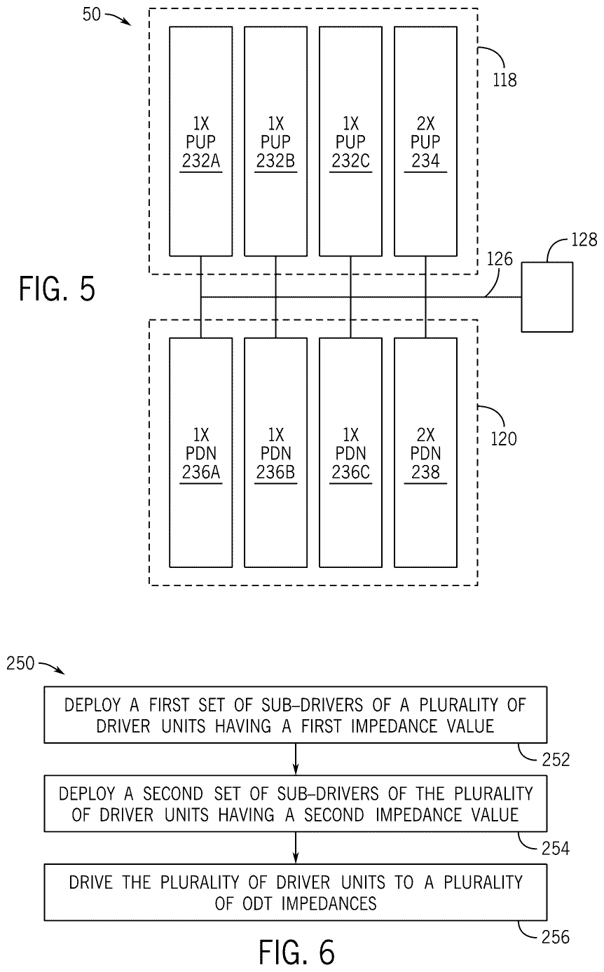

For instance, FIG. 5 shows a block diagram of the output driver 50 with heterogeneous sub-drivers. As previously discussed, the output driver 50 may drive to different impedances (e.g., during ODT), but the embodiment in FIG. 5 includes sub-drivers that have different impedances. As illustrated, the driver units 118 may include multiple sub-driver units 232 that have a 1× impedance (e.g., 120Ω. In other words, each of sub-driver units 232A, 232B, and 232C may be similar to the sub-driver units previously discussed. However, in some embodiments, the impedance of the driver units 232 may be equal to the RZQ 54 that may be a different value, such as 120Ω, than that described above since calibration to 120Ω may still provide the ability to the required impedance values for ODT using the heterogeneity of the impedances sub-drivers. As such, in the heterogeneous impedance embodiment of the circuitry 230, at least one sub-driver unit, such as sub-driver unit 234 may have a different impedance (e.g., 2× or 240Ω. For instance, if the sub-drivers 232 are calibrated to 120Ω using an RZQ 54 that has the same impedance value, the driver unit 118 may provide the same impedances with fewer sub-drivers in exchange for some linearity loss. For instance, Table 1 shows target impedances by specification and the homogeneous (e.g., FIG. 3) and heterogenous (e.g., FIG. 5) parallel sub-driver units connections to obtain such results.

TABLE 1
Heterogeneous and Homogeneous Sub-Driving ODT Strengths

| ODT Value | Heterogeneous | Homogeneous |
|---|---|---|
| 240 | 1 240 Ω sub-driver | 1 240 Ω sub-driver |
| 120 | 2 240 Ω sub-drivers | 1 120 Ω sub-driver |
| 80 | 3 240 Ω sub-drivers | 1 240 Ω sub-driver parallel to |
| | | 1 120 Ω sub-driver |
| 60 | 4 240 Ω sub-drivers | 2 120 Ω sub-drivers |
| 48 | 5 240 Ω sub-drivers | 1 240 Ω sub-driver parallel to |
| | | 2 120 Ω sub-drivers |
| 40 | 6 240 Ω sub-drivers | 3 120 Ω sub-drivers |
| 34.29 | 7 240 Ω sub-drivers | 1 240 Ω sub-driver parallel to |
| | | 3 120 Ω sub-drivers |

As illustrated, the driver units 122 of the output driver 50 may include multiple sub-driver units 236 that have a 1× impedance (e.g., 120Ω. In other words, each of sub-driver units 236A, 236B, and 236C may be similar to the sub-driver units previously discussed. However, in some embodiments, the impedance of the driver units 236 may be equal to a multiple of the RZQ 54 that may be a different value, such as 120Ω, than that described above since calibration to 120Ω may still provide the ability to the required impedance values for ODT using the heterogeneity of the impedances sub-drivers. As such, in the heterogeneous impedance embodiment of the circuitry 230, at least one sub-driver unit, such as sub-driver unit 238 may have a different impedance (e.g., 2× or 240Ω. For instance, if the sub-drivers 236 are calibrated to 120Ω using an RZQ 54 that has the same impedance value, the driver unit 122 may provide the same impedances with fewer sub-drivers. For instance, the driver unit 122 may utilize the Table 1 heterogeneous column.

FIG. 6 is a flow diagram of a process 250 for using the memory device 10. As illustrated, the memory device 10 deploys a first set of sub-drivers of multiple driver units with a first impedance value (block 252). For instance, the ZQC 48 may provide a calibration code used to calibrate the sub-drivers 232 and 236 to an impedance of the ZQ resistor (e.g., 120Ω. The memory device 10 further deploys a second set of the sub-drivers of the plurality of driver units with a second impedance value (block 254). For instance, the sub-drivers 234 and 238 have different impedance. This different impedance may be a multiple (e.g., 2× or 3×) of the sub-drivers 232 and 236. For instance, the second impedance value may be 240Ω that is 2× the impedance 120Ω of the ZQ resistor.

The memory device 10 then drives the driver units to one of multiple ODT impedances (block 256). A number of the multiple ODT impedances is greater than a number of sub-drivers per each driver unit of the multiple driver units. In some embodiments, the number of ODT impedances may be defined by a DDR standard specification. For instance, the number of ODT impedances may be seven while the number of sub-drivers per each driver unit is four.

Furthermore, in some embodiments, driving the units may include setting a calibration code. For instance, the calibration code may be output from a respective counter, such as the counters 70 and/or 86. In some embodiments with the reduced number of sub-drivers, the memory device may use fewer bits than the calibration code by omitting a bit (e.g., a most-significant bit (MSB)) from the calibration code and shifting the control bits to reduce the number of control bits to reduce area consumption in exchange for more quantization error at lower ODT impedances. Alternatively, the calibration codes may be designed to 240Ω and used for 120Ω values similarly with the same codes and numbers of bits.

While the present disclosure may be susceptible to various modifications and alternative forms, specific embodiments have been shown by way of example in the drawings and have been described in detail herein. However, it should be understood that the present disclosure is not intended to be limited to the particular forms disclosed. Rather, the present disclosure is intended to cover all modifications, equivalents, and alternatives falling within the spirit and scope of the present disclosure as defined by the following appended claims.

The techniques presented and claimed herein are referenced and applied to material objects and concrete examples of a practical nature that demonstrably improve the present technical field and, as such, are not abstract, intangible, or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112 (f). However, for any claims containing elements designated in any other manner, it is intended that such elements are not to be interpreted under 35 U.S.C. 112 (f).

What is claimed is:

1. A memory device, comprising:
ZQ calibration circuitry comprising a ZQ resistor; and
one or more output drivers comprising a plurality of driver unit circuitries configured to be calibrated using the ZQ calibration circuitry using a calibration code, wherein at least one of the plurality of driver unit circuitries comprises a plurality of sub-drivers, wherein the plurality of sub-drivers comprises:
a first set of sub-drivers each having a first impedance; and
a second set of sub-drivers each having a second impedance that is different than the first impedance.

2. The memory device of claim 1, wherein the second impedance is double the first impedance.

3. The memory device of claim 2, wherein the first impedance is 120Ω, and the second impedance is 240 Ω.

4. The memory device of claim 1, wherein the first set of sub-drivers comprises three times as many sub-drivers as the second set of sub-drivers.

5. The memory device of claim 1, wherein the each of the plurality of driver unit circuitries comprises a respective plurality of sub-drivers that each comprises the first set of sub-drivers and the second set of sub-drivers.

6. The memory device of claim 5, wherein the first set of sub-drivers comprises three sub-drivers each having the first impedance, wherein the ZQ resistor also has the first impedance.

7. The memory device of claim 6, wherein the second set of sub-drivers comprises one sub-driver having the second impedance that is a multiple of the first impedance.

8. The memory device of claim 7, wherein the first impedance is 120Ω, and the second impedance is 240 Ω.

9. The memory device of claim 1, wherein each of the plurality of driver unit circuitries consists of four sub-drivers that are configured to provide seven different impedance values.

10. The memory device of claim 9, wherein the seven different impedance values are configured to provide on-die termination for the memory device.

11. The memory device of claim 1, wherein each of the plurality of sub-drivers within each of the plurality of driver unit circuitries are connected in parallel to each other.

12. A method, comprising:
deploying a first set of sub-drivers of a plurality of output driver units having a first impedance value that matches an impedance of a ZQ resistor;
deploying a second set of sub-drivers of the plurality of output driver units having a second impedance value different than the first impedance value; and
driving the plurality of driver units to a plurality of on-die termination (ODT) impedances at different times, wherein a number of the plurality of ODT impedances is greater than a number of sub-drivers per each driver unit of the plurality of driver units.

13. The method of claim 12, wherein the number of the plurality of ODT impedances is seven, and the number of sub-drivers per each driver unit is four.

14. The method of claim 12, wherein the second impedance value is a multiple of the first impedance value.

15. The method of claim 12, wherein the second impedance value is double the first impedance value.

16. The method of claim 12, wherein driving the plurality of driver units comprises setting a calibration code for the plurality of driver units using ZQ circuitry and based on a ZQ calibration to control operation of transistors in the first set of sub-drivers and the second set of sub-drivers.

17. The method of claim 16, wherein driving the plurality of driver units comprises using fewer bits for the calibration code than output from a respective counter of the ZQ circuitry by omitting a most significant bit of the calibration code.

18. A memory device, comprising:
ZQ calibration circuitry comprising a ZQ resistor having a first impedance value; and
one or more output drivers comprising a plurality of driver unit circuitries configured to be calibrated using the ZQ resistor, wherein at least one of the plurality of driver unit circuitries comprises a plurality of sub-drivers, wherein the plurality of sub-drivers comprises:
a first sub-driver having a first plurality of transistors and first one or more resistors that in total have the first impedance value;
a second sub-driver having a second plurality of transistors and second one or more resistors that in total have the first impedance value;
a third sub-driver having a third plurality of transistors and third one or more resistors that in total have the first impedance value; and
a fourth sub-driver having a fourth plurality of transistors and fourth one or more resistors that in total have a second impedance value that is different than the first impedance value.

19. The memory device of claim 18, wherein the plurality of sub-drivers are configured to select between a plurality of on-die termination levels, the configurable on-die termination levels are specified by a DDR specification, and the number of the configurable on-die termination levels is greater than the number of sub-drivers in a respective driver unit.

20. The memory device of claim 18, where the second impedance value is an integer multiple of the first impedance value.
